(19) United States
(12) Patent Application Publication
(10) Pub. No.: US 2007/0195877 A1
(43) Pub. Date: Aug. 23, 2007

(54) Arbitrary pulse generation

(76) Inventors: Martin Muecke, Stuttgart (DE); Joachim Moll, Herrenberg (DE)

Correspondence Address: PERMAN & GREEN, 425 POST ROAD, FAIRFIELD, CT, 06824, US

(21) Appl. No.: 11/789,595

(22) Filed: Apr. 25, 2007

(30) Foreign Application Priority Data
Oct. 28, 2004 (EP) PCT/EP04/52698

(51) Int. Cl. H03K 9/04

(52) U.S. Cl. 375/239

(57) ABSTRACT

The present invention relates to a method and a corresponding system for generating a binary pulse stream (37) based on a stable clock (76), said method being characterized by the steps of: reading a sequence of pairs of values representing LOW and HIGH state duration, respectively, of consecutive pulses of said binary pulse stream (37), said pairs of values being related to said stable clock (76), providing for each value an integral multiple part and a fractional part of the cycle time of said stable clock (76), using said integral multiple part for controlling an edge forming unit (40), said edge forming unit (40) contributes said integral multiple part of the duration of the respective state of the respective pulse to said binary pulse stream (37) to be generated, and using said fractional part for controlling a delay modulation unit (42), said delay modulation unit (42) prolongs, according to said fractional part, the duration of the respective state of the respective pulse to said binary pulse stream (37) to be generated.

### BACKGROUND OF THE INVENTION

The present invention relates to an improvement in generating a binary pulse stream. The generated pulse stream may also represent a data stream. In particular the present invention relates to an increase of the freedom of choice of timing parameters describing each individual pulse of such pulse streams.

A binary pulse stream can be understood as a sequence of individual pulses. Each individual pulse is defined by the duration of its LOW state and the duration of its HIGH state, and the duration of the HIGH state is defined by the time between a leading edge and a trailing edge of a corresponding individual pulse. The sum of the duration of the LOW state and of the duration of the HIGH state will also be referenced as the period of the pulse. The reciprocal value of an oscillator frequency will be referenced as cycle time of the oscillator.

Generators for generating a binary pulse stream are known from prior art. Those generators generally include three individual oscillators to influence the timing parameters of an outgoing pulse. To change timing parameters of an individual pulse one or more of these oscillators have to be tuned, and during such a tuning process it will take some time for an oscillator to settle to a new frequency, especially settling may take more than one cycle time of the actual frequency of the corresponding oscillator.

It is a well known practice to use a counter following an individual oscillator if the tuning range of the individual oscillator is not sufficient to get large periods, delays or widths of the outgoing pulse. Beside the mentioned settling time needed, the prior art oscillators suffer from a low Q-factor (quality factor or figure of merit) of the oscillator needed to stimulate oscillation resulting in a relatively high jitter of their output signals which will be forwarded to an outgoing pulse. In addition, those oscillators show a temperature dependency of their output frequency leading to a reduced accuracy of a pulse generated using such oscillators.

Thus a quick change of timing parameters and/or changes over a wide range of all timing parameters of an individual pulse are not feasible using those prior art techniques. In addition, the prior art oscillators followed by counters will force the timing parameters, e.g. period, duration of LOW state, and duration of HIGH state to be multiples of the cycle time of the individual oscillators and will not allow for a free choice of timing parameters consisting of multiple and fractional parts of the cycle times of the individual oscillators.

### SUMMARY OF THE INVENTION

It is an object of the invention to provide an improved method and a corresponding system for generating a binary pulse stream, in particular to provide a method for changing quickly the timing parameters of each individual pulse, namely the duration of the LOW state and/or the duration of the HIGH state. It is a further object of the invention to provide a method allowing for a high resolution in the choice of timing parameters of individual pulses. It is still a further object of the invention to provide a digital solution based on stable clock source avoiding analog circuits with their inherent finite settling times, temperature dependencies and other disadvantages.

The objects are achieved as defined by the independent claims. Preferred embodiments are defined by the dependent claims.

As mentioned above the duration of the HIGH state of each individual pulse is defined by the time between the leading edge and the trailing edge of the respective individual pulse. Accordingly, the duration of the LOW state of each individual pulse is defined by the time between the trailing edge and the leading edge of the respective individual pulse. Thus a pulse stream of consecutive pulses may be defined by a sequence of pairs of values representing the durations of LOW and HIGH state of each individual pulse. The duration of the LOW state may also be regarded as a delay until the state changes from LOW to HIGH, and the duration of the HIGH state may also be regarded as a delay until the state changes from HIGH to LOW. Thus from a more general perspective, the binary pulse stream to be generated can be defined as a sequence of delays.

Although also constant pulse rates may be generated, the inventive method is not limited to constant pulse rates and based upon the sequential description of the pulse stream described above allows for an arbitrary choice of the timing parameters for each individual pulse.

The pulse stream generated by the inventive method may be used for general measurement equipment but may also represent a data stream which may comprise either “return to zero” or “non return to zero” encoded data. A short description of the invention is presented here, whereas more detailed description of particular units showing a more detailed view will be presented within the description of the drawings.

In an embodiment of the invention said sequence of pairs of values representing LOW and HIGH state duration have to be provided as an input signal. The timing parameters given by this sequence may be either read from memory, or read from a direct input via a suitable interface which may either be connected to an external memory or to an input device, e.g. a keyboard or a touch screen.

In a preferred embodiment, the binary pulse stream to be generated is based on a stable clock source and the format of the input data is different for two different operation modes of the inventive method. In both operation modes an edge forming unit as well as a delay modulation unit is controlled by digital control words. Said edge forming unit is controlled by a first digital control word, which is referenced as first control word in the following description. A first part of said first control word determines the type of edge, i.e. leading or trailing edge. A second part of said first control word represents a part of the duration of the respective state that can be expressed as integral multiples of the cycle time of said stable clock. The delay modulation unit is controlled by a second digital control word, which is referenced as second control word in the following description. The delay modulation unit delays an edge formed by said edge forming unit according to said second control word. The first control word and the second control word have a predetermined format.

The input for the first control word at the edge forming unit may be switched between two sources related to the two modes of operation mentioned above using a first switch. The input for the second control word at the delay modulation unit may be switched between two sources related to the two modes of operation using a second switch.

In said first mode of the method of the invention a direct data input of the inventive system is used. Said direct data are preprocessed and thus provided in a format which allows using the direct data as input data for the edge forming unit and the delay modulation unit. In particular the direct date represents the first and second control words, e.g. the direct data comprises—or is even simply composed of—the first and second control word. In a preferred embodiment, a plurality of direct data lines are provided in parallel at a relatively low data rate to an input of a high-speed multiplexer which outputs the direct data consecutively at a higher data rate.

In a second mode of operation control data representing the sequence of pairs of values of LOW and HIGH state duration of the intended pulse stream are used. The control data may be time values and/or may be read out from memory. The control data need to be converted into first and second control words for the edge forming unit and the delay modulation unit.

This conversion is accomplished comprising two steps. First a management unit is used to split up the control data into a preliminary integral multiple part and a preliminary fractional part of the value of the respective state duration expressed in terms of cycle ti me of a derivative clock. The cycle time of this derivative clock is preferably larger than the cycle time of the stable clock, in particular the cycle time of the is derivative clock is an integral multiple of the cycle time of said stable clock.

Second, the preliminary integral multiple part is fed into a counter element of a counter and adder unit and sa id preliminary fractional part is fed into an adder element of said counter and adder unit. The counter and adder unit accomplishes a further preparation of the preliminary integral multiple part and of the preliminary fractional part. At the output of the counter and adder unit a toggle signal and a data word is provided, said data word comprising the second control word for controlling the delay modulation unit and components of the first control word for controlling the edge forming unit. The toggle signal and the components of the first control word are associated to form the first control word, e.g. by a pulse formatter. Instead of the preliminary first control word, or in combination, data read out from a memory may be supplied to the pulse formatter to be associated with the toggle signal.

The edge forming unit comprises an encoder encoding said first control word in an edge control word, said edge control word comprising maximally two blocks of bits, each bit of said maximally two blocks being either “0” or “1”. Subsequently, the edge control word is transformed, e.g. by a multiplexer having a number of parallel inputs according to the number of bits contained in said maximally two blocks, into a series of bits in the sequence of the bits in the maximally two blocks of bits, thus forming the edge. In case of forming a leading edge, the series of bits comprises one or more “1” to which one or more “0” may precede. In case of forming a trailing edge, the series of bits comprises one or more “0” to which one or more “1” may precede.

In a preferred embodiment the frequency of said clock is adjustable to avoid unwanted spurious signals from the delay modulation unit and/or to provide a desired output frequency.

The present invention also relates to a software program of product for executing the method for generating a binary pulse stream when running on a data processing system such as a computer. Preferably the program of product is stored on a data carrier.

Furthermore the present invention relates to a system generating a binary pulse stream according to the present invention.

### BRIEF DESCRIPTION OF THE DRAWINGS

Other objects and many of the attendant advantages of the present invention will be readily appreciated and become better understood by reference to the following description, taken in conjunction with the accompanying drawings, in the several figures of which like reference numerals identify like elements, and in which:

FIG. 1 shows a prior art system for generating a binary pulse stream;

FIG. 2 shows the block diagram of the inventive system;

FIG. 3 shows a raw block diagram of the inventive system;

FIG. 4 shows a first embodiment of the delay modulation unit of the inventive system;

FIG. 5 shows a second embodiment of the delay modulation unit of the inventive system;

FIG. 6 shows a detailed block diagram of an embodiment of the inventive system;

FIG. 7 shows a timing diagram and according register contents for a sample of an individual pulse to be generated;

FIG. 8 shows a timing diagram of a further individual pulse to be generated;

FIG. 9a to FIG. 9e show a detailed view of the counter and adder with digital states of this circuit for the pulse according to FIG. 8

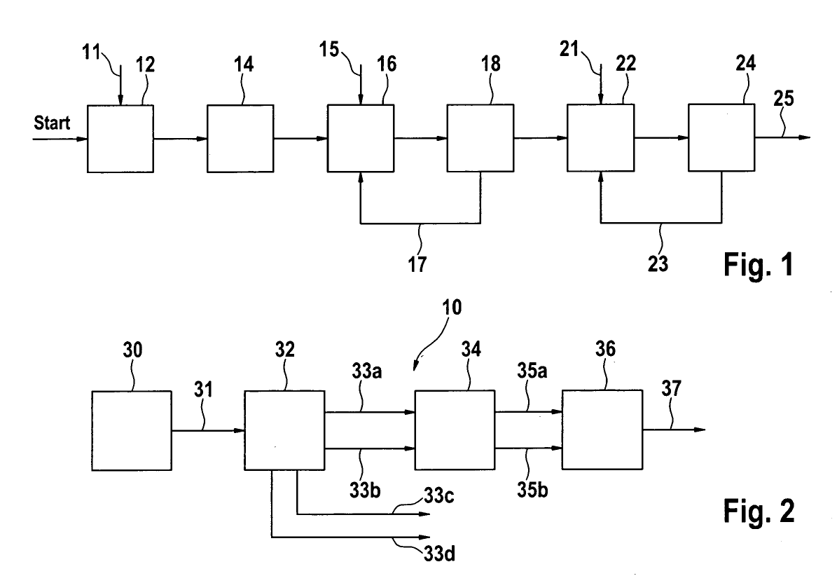

FIG. 1 shows a block diagram of a pulse generator known from prior art. A start signal triggers the period oscillator 12 and the frequency of the period oscillator 12 may be tuned at the period tuning input 11 of period oscillator 12. The output signal of period oscillator 12 is fed into the period counter 14, said period counter 14 dividing the frequency of the period oscillator by a factor N. The output of the period counter 14 feeds the delay oscillator 16 which may be tuned at its delay tuning input 15. The output signal of the delay oscillator 16 is fed to the delay counter 18 which divides the frequency by the factor of N and feeds back a stop signal 17 to the delay oscillator 16. Output signal of the delay counter 18 is fed into the width oscillator 22 which may be tuned at its width tuning input 21. The output signal of the width oscillator 22 is fed into the width counter 24. The width counter 24 divides the frequency by the factor of P. A stop signal 23 is fed back from the width counter 24 to the width oscillator 22. At the output 25 of the width counter 24 a generated pulse stream is available.

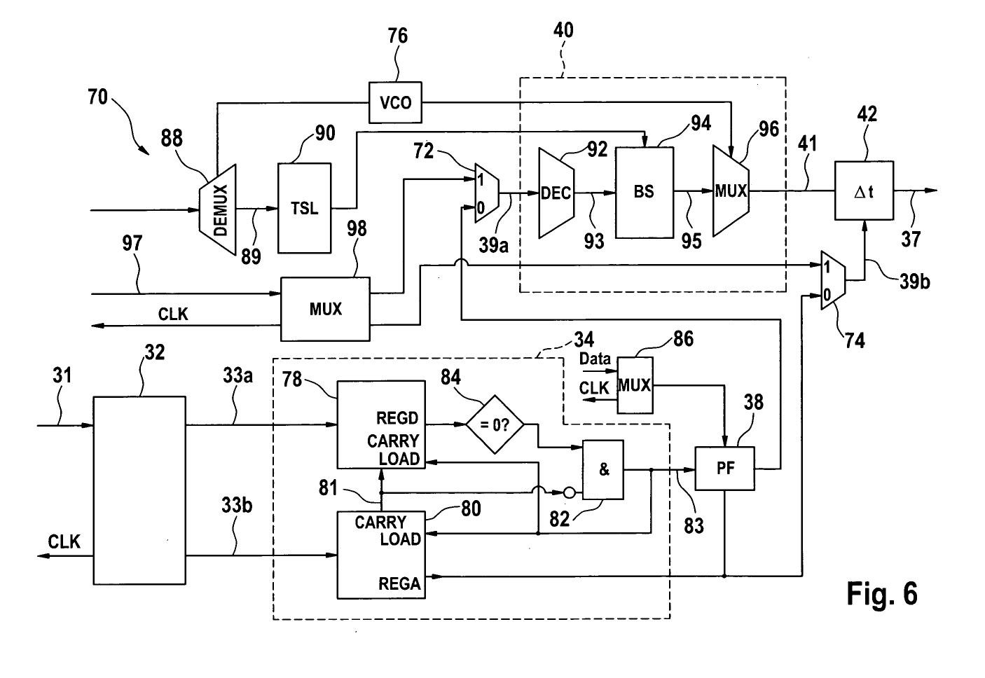

FIG. 2 shows a block diagram of a system 10 executing the inventive method to generate a binary pulse stream 37 by processing a sequence of pairs of values representing LOW and HIGH state duration, respectively, of consecutive pulses of said binary pulse stream 37, said pairs of values being related to said stable clock 76 (see FIG. 6), providing for each value an integral multiple part and a fractional part of the cycle time of said stable clock 76, using sa id integral multiple part for controlling an edge forming unit 40, said edge forming unit 40 contributes said integral multiple part of the duration of the respective state of the respective pulse to said binary pulse stream 37 to be generated, and using said fractional part for controlling a delay modulation unit 42, sa id delay modulation unit 42 prolongs, according to said fractional part, the duration of the respective state of the respective pulse to said binary pulse stream 37 to be generated.

The inventive system comprises a memory unit 30 providing control data 31 representing the sequence of pairs of values of LOW and HIGH state duration of the binary pulse stream 37 to be generated. The control data 31 are fed to a management unit 32 which provides a preliminary integral multiple part 33a and a preliminary fractional part 33b of the value of the respective state duration expressed in terms of cycle time of a derivative clock which is described in more detail below. Additionally the management unit 32 may provide a trigger signal 33c and a strobe signal 33d. The preliminary integral multiple part 33a and the preliminary fractional part 33b are fed to a counter and adder unit 34 providing a toggle signal 35a and a data word 35b, said data word 35b comprising a second control word for controlling the delay modulation unit 42 and components of a first control word for controlling the edge forming unit 40. The toggle signal 35a and the data word 35b are fed to a a pulse generation block 36 comprising the edge forming unit 40 and the delay modulation unit 42. At the output of the pulse generation block 36 the binary pulse stream 37 to be generated is available.

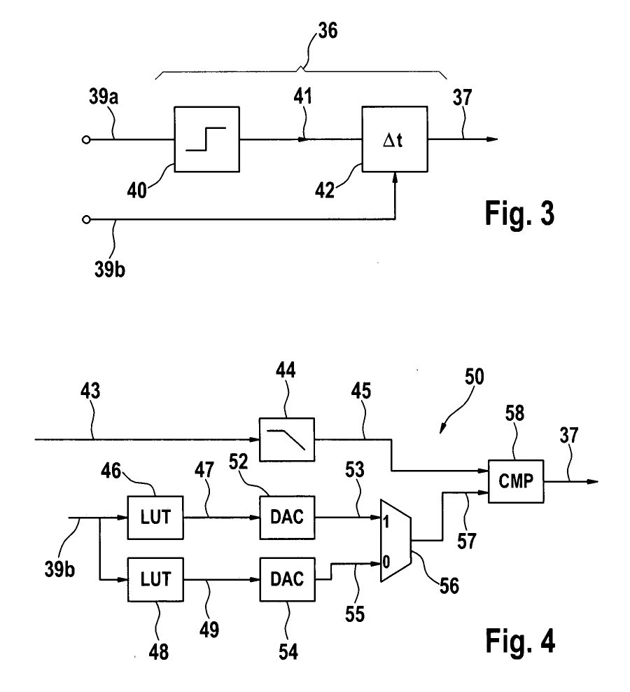

FIG. 3 shows a raw block diagram of the inventive system. An edge forming unit 40 forms a leading or trailing edge of the pulse stream 37 to be generated according to a first control word 39a. The edge can only be placed at discrete points in time spaced by the cycle ti me of the stable clock 76. The output signal 41 of the edge forming unit 40 is fed into a delay modulation unit 42. This delay modulation unit 42 delays the edge by a time value which is defined by a second control word 39b and provides the pulse stream 37 to be generated at its output.

FIG. 4 shows a first embodiment 50 of the delay modulation unit 42 of the inventive system 10 comprising a ramp generator 44 which is triggered by an input signal 43, which can be formed by the output signal 41 of the edge forming unit 40. The output signal 45 of the ramp generator 44 is fed into a comparator 58. The second control word 39b is fed to a first look-up table 46 and to a second look-up table 48. The output signal 47 of the first look-up table 46 is fed into a first digital-to-analog converter 52. The output signal 49 of the second look-up table 48 is fed into a second digital-to-analog converter 54. One of the two paths comprising a look-up table 46, 48 and a digital-to-analog converter 52, 54 is optimized for delaying a leading edge, whereas the remaining path is optimized for delaying a trailing edge.

The output signal 53 of the first digital-to-analog converter 52 and the output signal 55 of the second digital-to-analog converter 54 are fed into a switch 56 allowing to select one of the two output signals 53, 55 to be fed to the output of the switch 56. The output signal 57 of the switch 56 is fed into a second input of the comparator 58. At the output of the comparator 58 the input signal 43 is delayed according to the second control word 39b, and thus the binary pulse stream 37 to be generated is available.

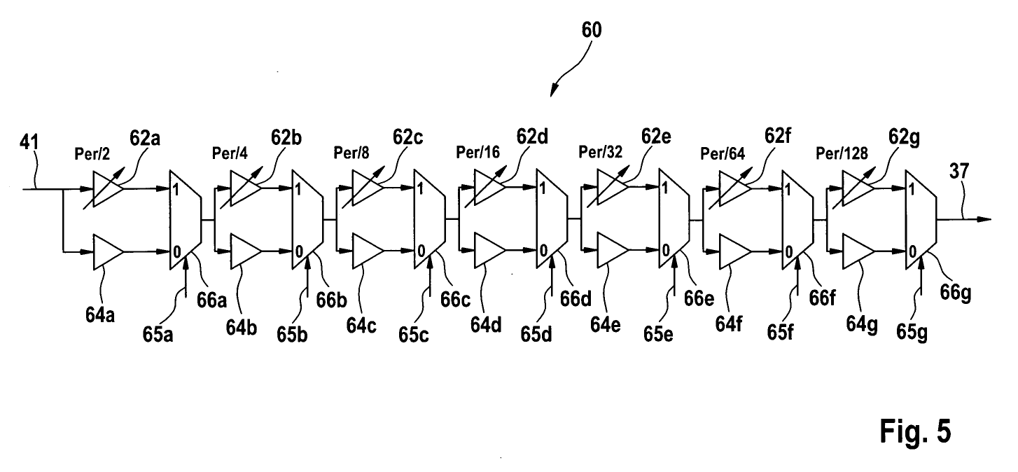

FIG. 5 shows a second embodiment 60 of the delay modulation unit 42 of the inventive system. According to the second embodiment 60 delay elements 62a to 62g are arranged sequentially by a repeated arrangement of in total seven groups being of the same structure. The left most group shown in FIG. 5 comprises a delay element 62a, a buffer element 64a, and a delay switch 66a. Each of the further groups also comprises, respectively, a delay element 62b to 62g, a buffer element 64b to 64g, and a delay switch 66b to 66g. Each of the delay switch elements 66a to 66g comprises a control input 65a to 65g. The control inputs 65a to 65g are fed by the second control word 39b. The number of groups depends on the desired resolution of the delay. The delay elements 62a to 62g of the groups are adjusted to different delays being fractions of the cycle time of a stable clock source 76, respectively. In the second embodiment 60, delay elements 62a to 62g of adjacent groups provide delays which differ by a factor of 2. For particular applications it is advantageous that the second embodiment 60 does not comprise look-up tables and/or digital-to-analog converters. Depending upon the respective value at the control inputs 65a to 65g the delay switches 66a to 66g select either a non-delayed path using the respective buffer element 64a to 64g or a delayed path via the respective delay element 62a to 62g.

FIG. 6 shows a detailed block diagram of an embodiment 70 of the inventive system comprising a stable clock 76, the edge forming unit 40, the delay modulation unit 42, a counter and adder unit 34, a pulse form after 38, and a first switch 72 and a second switch 74. The first switch 72 and second switch 74 are used to switch between two modes of operation.

In the first mode of operation direct data 97 are fed to a multiplexer 98. Said direct data 97 are preprocessed and thus provided in a format which allows using the direct data 97 as input data for the edge forming unit 40 and the delay modulation unit 42. In particular the direct data 97 represent the first and second control words 39a, 39b, e.g. the direct data 97 comprises—or is even simply composed of—the first and second control word 39a, 39b. In the shown embodiment, a plurality of direct data lines are provided in parallel at a relatively low data rate to an input of a high-speed multiplexer 98 which outputs the direct data consecutively at a higher data rate. Furthermore the mulitplexer 98 provides a clock signal CLK for synchronization purposes.

In the second mode of operation control data 31 are used describing the binary pulse stream 37 to be generated, said control data 31 can be read from a memory unit 30 as shown in FIG. 2. Despite the format of the input data used in the first mode, the input data used in the second mode may be in a very basic format like duration of the LOW state and duration of the HIGH state of individual pulses of the binary pulse stream 37, said values e.g. given in nanoseconds. Those data are converted by the management unit 32 for being used by the inventive system. At the output of the management unit 32 a preliminary integral multiple part 33a and a preliminary fractional part 33b of the value of the respective state duration expressed in terms of cycle time of a derivative clock is provided to the counter and adder unit 34, which in conjunction with the pulse formatter 38 further prepares the data to be used by the edge forming unit 40 and the delay modulation unit 42. Furthermore the management unit 32 provides a clock signal CLK for synchronization purposes.

Driven by a start signal and the stable clock 76 a demultiplexer 88 provides its output signal 89 to a trigger start logic 90 which is used to prepare a control signal for the barrel shifter 94 within the edge forming unit 40. The edge forming unit 40 comprises at its input a decoder 92 and the output 93 of the decoder 92 is fed to the barrel shifter 94. The output 95 of the barrel shifter 94 is provided to the multiplexer 96. The output 41 of the multiplexer 96 drives the delay modulation unit 42 which can be realized either as shown in FIG. 4 or 5.

The counter and adder unit 34 comprises a counter 78, a digital comparator 84, a toggle element 82, and an adder 80. At the input of the counter and adder unit 34 the preliminary integral multiple part 33a and the preliminary fractional part 33b, representing respectively the duration of a LOW state or the duration of a HIGH state of an individual pulse, are provided such that the duration is split up into an integral multiple part of the cycle time T_{D}. The cycle time T_{D} is an integral multiple of the cycle T_{CLOCK} of the stable clock 76. For the embodiment shown in FIG. 6 T_{D} is 8 times T_{CLOCK}.

The preliminary integral multiple part 33a is loaded into register D within the counter 78. The preliminary fractional part 33b is added to the register A of adder 80. The adder 80 may output on line 81a carry bit which is fed to the counter 78 and to the toggle element 82. The output signal 83 of the toggle element 82 is provided to pulse formatter 38 and also as a LOAD signal to adder 80 and counter 78. The digital comparator 84 checks the content of register D of counter 78. If the content equals zero, the digital comparator 84 will provide a HIGH level to an input of the toggle element 82. In all other cases the digital comparator 84 provides a LOW signal to an input of the toggle element 82. The output 83 of the toggle element 82 will only be HIGH if the carry output of adder 80 is LOW and the output of the digital comparator 84 is HIGH. In all other cases the output 83 of the toggle element 82 will be LOW The pulse formatter 38 may receive external data from a multiplexer 86 to which external data are fed, e.g. received from a memory, and which provides a clock signal for synchronization purposes. The content of the register A of adder 80 is read out and components, i.e. a part of the more significant bits, is split up to be provided to the pulse formatter 38, whereas the lower significant bits are provided to the second switch 74.

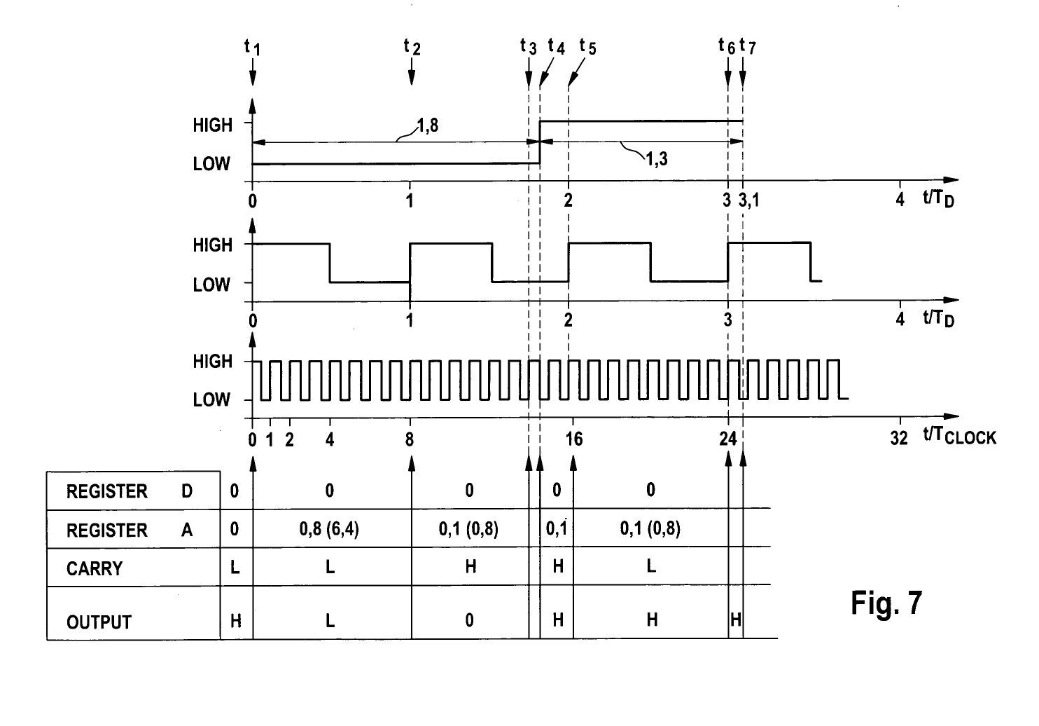

FIG. 7 shows a timing diagram and according register contents as well as state of the carry bit and the state of the output pulse at the delay modulation unit 42 of FIG. 6. The timing diagram is used to clarify functions of parts of the counter and adder unit 34, in particular the generation of an individual pulse comprising a LOW state and a HIGH state. FIG. 7 shows three signal traces. The upper curve shows an individual pulse of the binary pulse stream 37 to be generated. The lowest curve shows the output signal of the stable clock 76 of FIG. 6 and the middle curve shows the derivative clock, wherein in this case the cycle time T_{D} of the derivative clock is eight times the cycle time T_{CLOCK} of the stable clock 76. Within the table shown at the lower part of FIG. 7 above-mentioned register contents and other signals are shown and the placement within one row of the table corresponds to the time given at the X-axis of the diagrams at which the values are present. In addition, seven discrete points in time are marked above the upper diagram by references t1 to t7.

For the individual pulse regarded here, the LOW state duration is 1.8×T_{D} and the HIGH state duration is 1.3×T_{D}. It is assumed that for times less than zero the content of register D and the content of register A are zero and the carry bit is LOW and the output signal is HIGH, as shown in the left most column of the table in FIG. 7. Beginning with these initial values now a short description follows what happens from time t1 to time t7:

t1: At t1 register D of counter and adder unit 34 are loaded with 0 because the integral multiple part of the LOW state duration of the pulse to be generated is 1 which is the minimum duration of the LOW state, and 0.8 is added to register A, the carry bit and the output state are LOW. The output changes from HIGH to LOW. In case a value in parenthesis follows a value given for a register content in the table, the value in parenthesis is based to T_{CLOCK}. Values given without parenthesis for register D and register A within the table are based to T_{D}.

t1 to t2: During the time from t1 to t2 values of register D, register A, carry bit and the output state remain constant. As Register D is zero and the Carry bit is zero, LOAD is one and at t2 the new Values for D and A will be written.

t2: At t2 the counter 78 is loaded with 0 because this integral multiple part of the high state duration of the pulse to be generated is 1 which is the minimum duration of the HIGH state, and the fractional part of the duration of the HIGH state is 0.3 and it is added to register A resulting in a sum of 1.1 and thus leads to a carry bit set to HIGH and the content of register A being 0.1. The fractional delay of 0.8 is transferred to the delay modulation block.

t2 to t3: The LOW state of the output signal is prolonged by 6×T_{CLOCK} corresponding to the integer multiple part of the content of prior register A based on T_{CLOCK} as seen by the value in parenthesis.

t3: At t3 the prolongation of the LOW state of the output described in the item above ends, but a further prolongation of the LOW state of the output is accomplished by the lower bits of the prior content of the register A which are sent to the second switch 74 and the output of the second switch 74 being sent to the delay modulation unit 42.

t3 to t4: During t3 to t4 the output state keeps being LOW according to the operation of the delay modulation units 60 of FIG. 4 as described in the item above.

t4: At t4 register D keeps being 0 (or less than 0, which is treated like being 0), the register A keeps being 0.1 T_{D}. No changes of the registers occur because register changes may only occur at leading edges of the derivative clock. The output changes from LOW to HIGH because delay of the delay modulation unit 42 now ends.

t5: Because the carry bit being HIGH, the counter 78 is stopped at t5 for one cycle time T_{D} of the derivative clock and thus the content of the register D remains constant. The output state is HIGH. Both Registers A and D remain unchanged. The carry bit is reset to zero.

t5 to t6: The register contents, the carry bit and the output state keep constant from t5 to t6.

t6: At t6 the register D is loaded with the integral part of the next LOW state, and the fractional part of the duration of the next LOW is added to register A resulting in new content of register A, which may leads to a carry bit set to HIGH. The prior content of register A being 0.1, which expressed on a base of T_{CLOCK} is 0.8. Thus the integral multiple part of the content of register A with reference to T_{CLOCK} is zero, and all more significant bits which are sent to the pulse formatter 38 in FIG. 6 are 0. The lower significant bits of the content of register A are forwarded to the second switch 74 and are provided to the delay modulation unit 42. The carry bit is set LOW and the output state is still HIGH.

t6 to t7: During t6 to t7 the state of the output of the delay modulation unit 42 of FIG. 6 is kept constant because the delay expressed by the lower bits of the prior contents of register A which have been sent to the control input of delay modulation unit 42 at t6.

t7: At t7 the delay of the delay modulation unit 42 passed and the delay modulation unit 42 releases a trailing edge.

As being obvious particularly from FIG. 7 and the corresponding description, the turn of values of a given pair of said pairs of values representing LOW and HIGH state duration, respectively, of consecutive pulses of said binary pulse stream 37, is arbitrary; in particular the sum does not have to be constant from pair to pair.

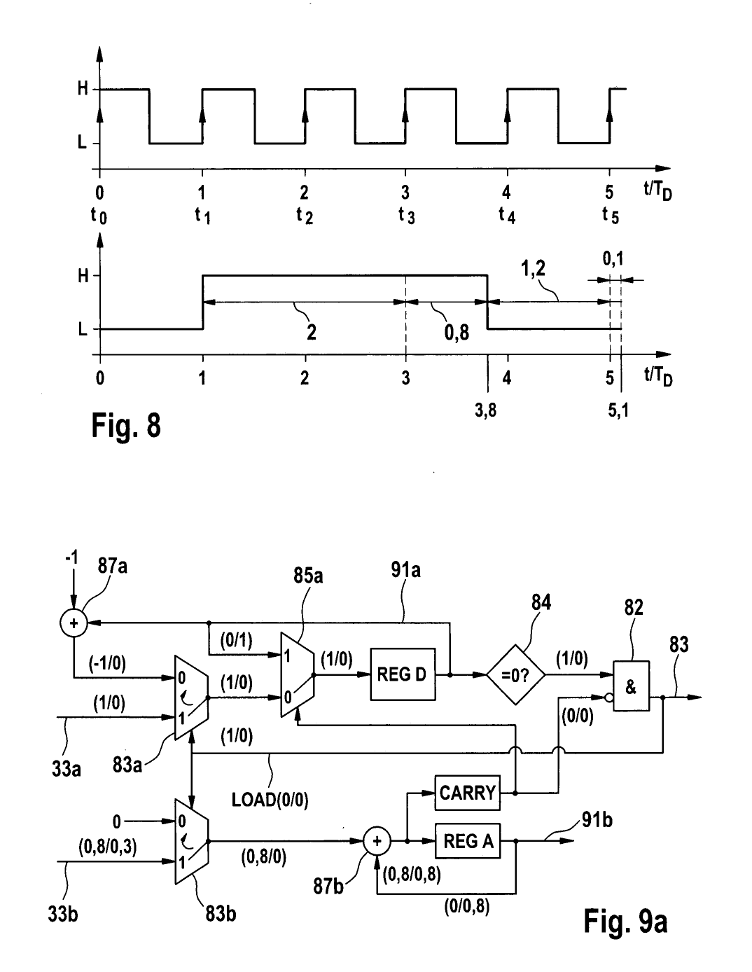

FIG. 8 shows a timing diagram of a further individual pulse to be generated. In this case an individual pulse with a HIGH state duration of 2.8 T_{D} and a LOW state duration of 1.3 T_{D} is generated. This pulse is shown in the lower curve of FIG. 8, whereas the upper curve shows the derivative clock signal having a cycle time of T_{D}.

The system does not allow for state durations smaller than 1 T_{D} and the HIGH state of the individual pulse here is starting at t=T_{D}. For t<T_{D} the LOW state of a previous individual pulse lasts. The time scale of both curves is established with a unit of T_{D}.

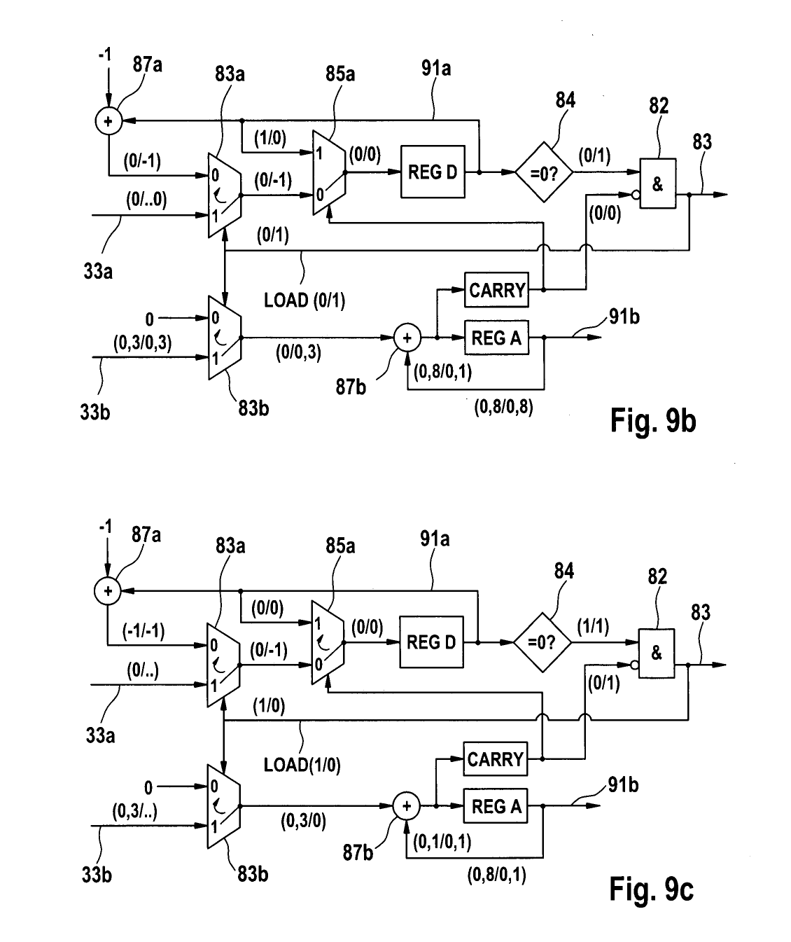

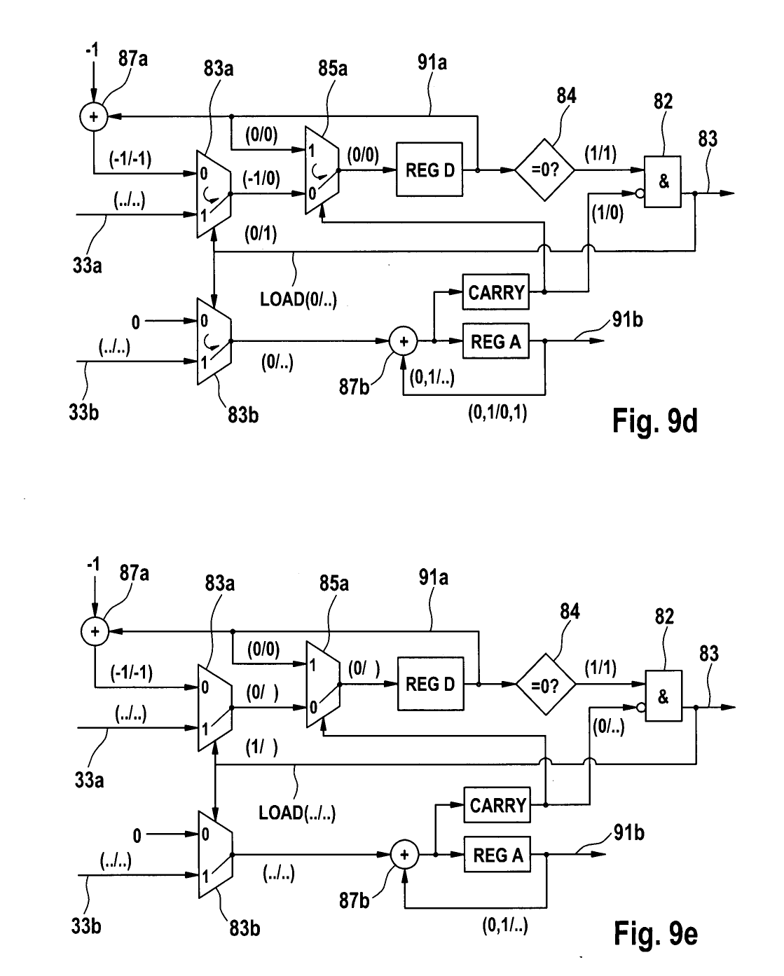

The lower curve shows the individual pulse starting with a leading edge at t=T_{D}, followed by a HIGH state lasting for 2.8 T_{D} and a LOW state lasting for 1.3 T_{D}. The generating of this pulse will be described using the FIGS. 9a to 9e.

FIGS. 9a to 9e show a detailed view of the counter and adder 34 with digital states and values of this circuit during generating the pulse according to FIG. 8. Because FIGS. 9a to 9e show a detailed view of the counter and adder 34 some more elements are visible. FIGS. 9a to 9e all show the same circuit; the only difference between them being that they show digital states and values, within round parenthesis. The digital states and values shown in each of FIGS. 9a to 9e correspond to an individual time range for each of these figures.

The additional elements will be described with reference to FIG. 9a. The upper part of FIG. 9a shows the counter, whereas the lower part shows the adder circuit. Output of Register D is fed back via line 91a to adder 87a and to the upper input of multiplexer 85a. The adder 87a decrements the input provided to it by line 91a by “1” and outputs the result to the upper input of multiplexer 83a, being marked by a “0” in a circle. Multiplexer 83a, 85a as well as multiplexer 83b in the lower part of FIG. 9a are 2:1 multiplexers. Multiplexers 83a, 83b will select the “1” input, marked by a “1” in a circle if a HIGH signal is present at the LOAD line controlling multiplexers 83a and 83b. Multiplexers 83a, 83b will select the “0” input, marked by a “0” in a circle if a LOW signal is present at the LOAD line controlling multiplexers 83a and 83b. Multiplexer 85a will select the “1” input, marked by a “1” in a circle if a HIGH signal is present at the CARRY line controlling multiplexer 85a. Multiplexer 85a will select the “0” input, marked by a “0” in a circle if a LOW signal is present at the CARRY line controlling multiplexer 85a. Outputs of the individual multiplexers 83a, 83b and 85a will be connected to the selected input according to the control described. The lower input of multiplexer 83a is fed by the preliminary multiple part 33a, whereas the lower input of multiplexer 83b is fed by the preliminary fractional part 33b. Output of multiplexer 83a is fed to the lower input of multiplexer 85a. Multiplexer 85a feeds its output to Register D. The output of multiplexer 83b is connected to an adder 87b. Adder 87b gets a second input signal provided by the output of Register A and adder 87b will output a HIGH level to the CARRY line in case its output is equal 1 or greater than 1. The content of Register A is available at its output 91b.

To get a more in-depth understanding of the behavior of the counter and adder circuit FIGS. 9a to 9e show the generating of the individual pulse shown in FIG. 8 as far as the counter and adder unit 34 is concerned. Referring to points in time t0 to t5 in FIG. 8 the following time ranges are described:

t0<t<=t1 in FIG. 9a;

t1<t<=t2 in FIG. 9b;

t2<t<=t3 in FIG. 9c;

t3<t<=t4 in FIG. 9d;

t4<t<=t5 in FIG. 9e.

t0, t1, t2 . . . , t5 are the points in time at which leading edges of the derivative clock, having a cycle time of T_{D} and shown in FIG. 8, occur. Only at these times a change of Register A, Register D and the CARRY line may happen.

The time ranges shown above for the individual FIGS. 9a to 9e are understood as follows: After a leading edge of the derivative clock signal shown in the upper curve of FIG. 8 the time range begins and it ends when the next leading edge of the derivative clock occurs. For example for FIG. 9c the time range is t2<t<=t3 and this means that the digital states given at first place in round parenthesis and the switch position of multiplexers 83a, 83b and 85a shown by a solid line within said multiplexers are valid at least up to t<t3, but may change at t3 with the occurrence of the leading edge of the derivative clock at t3. The changes occurring at the leading edge of the derivative clock at the end of the respective time range, i.e. at t=t3, are represented by the digital states given at second place following the slash symbol. A small arrow indicates the direction in which a switch of said multiplexers will be directed to at t=t3, if such a switch will change its state. For the figure that follows, i.e. FIG. 9d following FIG. 9c, the digital states shown at the second place in round parenthesis in FIG. 9c will be shown at first place in front of the slash. The switch positions of multiplexers 83a, 83b and 85a will be shown in FIG. 9d according to the arrows indicating a change in FIG. 9c, if applicable. FIGS. 9c and 9d were chosen just as an example for explanation purposes and accordingly any other two consecutive figures out of FIG. 9a to FIG. 9d may have been chosen.

Note that the system may only generate pulses with duration of HIGH states being at least T_{D} and with duration of LOW states being at least T_{D}.

In case a negative number “−1” is shown within said round parenthesis indicating a value in FIGS. 9a to 9e this value is just a numerical results and will Not be used within the circuit by a counter.

FIG. 9a, t0<t<t1: LOAD=1 and CARRY=0 force the multiplexers 83a, 83b and 85a into the shown switch position. This will allow new values for preliminary multiple part 33a to be red into REG D and preliminary fractional part 33b to be added by adder 87b with the next leading edge of the derivated clock at t1. Content of REG D=0 and content of REG A=0.

FIG. 9a; t=t1: Leading edge of the derivated clock occurs. REG D is loaded with value 1, adder 87b adds 0 provided by the output of REG A to the value 0.8 representing the preliminary fractional part 33b. At the output of REG A now the value 0.8 is present. With REG D now changing from 0 to 1 the digital comparator 84 will output 0, the output of toggle element 82 will toggle, thus LOAD will become 0 and multiplexers 83a and 83b will switch into the position indicated by arrows. CARRY remains 0. The output of adder 87a will change from 0 to −1.

Limiting the description to the points in time when the individual pulse to be generated transits from one state to the other, now the HIGH-to-LOW transition at time t=3.8 T_{D} will be described. The duration of the HIGH state to be generated is 2.8 T_{D}. REG D is loaded with 1 only and not with 2 because the minimum duration 1 T_{D} is inherent.

FIG. 9c; t=t3: The CARRY is set to HIGH at this time. The adder 87b is adding the 0.8 present from the output 91b of REG A to the value 0.3 present from the input of the preliminary fractional part 33b. The result of 1.1 leads to said CARRY being set for one clock cycle and the remaining rest 0.1 being forwarded to the REG A. For the next LOW state a duration of 1.3 is intended, but because of the inherent duration T_{D} of each state, only the value 0.3 is read in and 0 is present for the preliminary multiple part at 33a.

FIG. 9d; t3<t<t4: with the CARRY set to HIGH, the decrementing of the counter is stopped and thus the output of REG D remains constant. The HIGH state of the output pulse is kept because the value of 0.8 T_{D}, being equal to 6.4 T_{CLOCK}, has been sent from REG A in part, namely the part of 0.4 T_{CLOCK}, to the pulse formatter 38, and in part, namely the part of 6.0 T_{CLOCK}, to the delay modulation unit 42.

At t=3.8 T_{D}, the delay expires and the output pulse changes from HIGH to LOW. At t=t4=4 T_{D}, the CARRY is set to LOW. The adder 87b is adding the 0.1 present from the output 91 b of REG A to the value 0 present from the upper input of multiplexer 83b.

FIG. 9e; t4<t<t5: with the output signal keeps constant due to the inherent minimum duration T_{D}. For t>t5, the LOW state of the output signal is prolonged for 0.1 T_{D} by the delay modulation unit 42, before a transition from LOW to HIGH occurs.

1. A method for generating a binary pulse stream based on a stable clock, comprising:
reading a sequence of pairs of values representing LOW and HIGH state duration, respectively, of consecutive pulses of said binary pulse stream, said pairs of values being related to said stable clock, and providing for each value an integral multiple part and a fractional part of the cycle time of said stable clock,
using said integral multiple part for controlling an edge forming unit, said edge forming unit assigning said integral multiple part to a duration of the respective state of the respective pulse to said binary pulse stream to be generated, and
using said fractional part for controlling a delay modulation unit, said delay modulation unit prolonging, corresponding to said fractional part, the duration of the respective state of the respective pulse to said binary pulse stream to be generated.

2. The method of claim 1, wherein the sum of said values of a given pair is arbitrary, in particular the sum does not have to be constant from pair to pair.

3. The method of claim 1, wherein said edge forming unit is controlled by a first control word having m bits, m being greater or equal than two, wherein a first part of said m bits represents the type of edge, and a second part of said m bits represents said integral multiple part.

4. The method of claim 1, wherein said delay modulation unity is controlled by a second control word having k bits, k being greater or equal than one, and in that said delay modulation unit delays said edge formed by said edge forming unit according to said second control word.

5. The method of claim 4, wherein said delay modulation unit comprises a comparator with a first input being controlled by a value read from at least one look-up table according to said second control word, and a second input being driven by a ramp function which is triggered by the edge to be delayed, and in that an output signal of said comparator represents said binary pulse stream.

6. The method of claim 4, wherein said delay modulation unit comprises a delay circuit being digitally programmable by said second control word, and in that said edge formed by said edge forming unit is delayed by said delay circuit according to said second control word.

7. The method of claim 1, wherein the frequency of said stable clock is adjustable.

8. The method of claim 1, wherein the output signal of the pulse generator is a data stream and comprises either “return to zero” or “non return to zero” encoded data.

9. A software program or product, stored on a computer readable medium, for executing the method of claim 1 when running on a data processing system.

10. A system for generating a binary pulse stream based on a stable clock,
said system comprising:
a management unit adapted for reading a sequence of pairs of values
representing LOW and HIGH state duration, respectively, of consecutive pulses of said binary pulse stream, said pairs of values being related to said stable clock, and for providing for each value an integral multiple part and a fractional part of the cycle time of said stable clock,
an edge forming unit adapted for assigning said integral multiple part to a duration of the respective state of the respective pulse to said binary pulse stream to be generated, and
a delay modulation unit adapted for prolonging, corresponding to said fractional part, the duration of the respective state of the respective pulse to said binary pulse stream to be generated.
